(19) United States
(12) Patent Application Publication
(10) Pub. No.: US 2025/0341772 A1
(43) Pub. Date: Nov. 6, 2025

(54) CONTAINER POD AND RELATED SYSTEMS AND METHODS

(71) Applicant: ENTEGRIS, INC., Billerica, MA (US)

(72) Inventors: Russ V. Raschke, Chanhassen, MN (US); Tyler Monforton, Chaska, MN (US)

(21) Appl. No.: 19/200,333

(22) Filed: May 6, 2025

Related U.S. Application Data
(60) Provisional application No. 63/643,077, filed on May 6, 2024.
(60) Provisional application No. 63/750,763, filed on Jan. 28, 2025.
(60) Provisional application No. 63/755,929, filed on Feb. 7, 2025.
(60) Provisional application No. 63/766,755, filed on Mar. 4, 2025.

(51) Int. Cl. G03F 1/66; G03F 7/00

(52) U.S. Cl. CPC G03F 1/66; G03F 7/70741

(57) ABSTRACT

Described are containers for storing, transporting, shipping or processing fragile devices such as photomasks, reticles, and semiconductor wafers, including in particular dual containment pods that include an outer pod adapted to contain an inner reticle pod, with the inner reticle pod containing a reticle.

### CROSS-REFERENCE TO RELATED APPLICATIONS

This application claims the benefit under 35 U.S.C. 119 of U.S. Provisional Patent Application No. 63/766,755 filed Mar. 4, 2025, U.S. Provisional Patent Application No. 63/755,929 filed Feb. 7, 2025, U.S. Provisional Patent Application No. 63/750,763 filed Jan. 28, 2025, and U.S. Provisional Patent Application No. 63/643,077 filed May 6, 2024, the disclosures of which are hereby incorporated herein by reference in their entirety.

### FIELD

The present disclosure relates to containers for storing, transporting, shipping or processing fragile devices such as photomasks, reticles, and semiconductor wafers. More particularly, the present disclosure relates to a dual containment pod that includes an outer pod adapted to contain an inner reticle pod, with the inner reticle pod containing a reticle.

### BACKGROUND

One of the many process steps used in fabricating microelectronic and semiconductor devices is photolithography. Broadly, photolithography involves selectively exposing a specially prepared substrate surface to a source of radiation using a patterned template to create a patterned surface layer on the substrate. The patterned template, referred to as a “mask” or “reticle,” is a flat, transparent or reflective plate that includes a pattern that is reproduced on the substrate surface by radiation that is passed through or reflected off the patterned template.

Photolithographic techniques use various wavelengths of radiation, including light in an ultraviolet range, light in a deep ultraviolet range, or light in an extreme ultraviolet range, referred to as extreme ultraviolet lithography (also known as EUV or EUVL). Extreme ultraviolet lithography is performed in an evacuated atmosphere (a low pressure environment or a “vacuum” environment) to minimize energy loss of EUV light from atmospheric gases. The reticle must therefore be moved between a cleanroom environment having an ambient (atmospheric) pressure condition, and the evacuated environment of a photolithography tool. Specialized devices referred to as “pods” or “reticle pods” are used to handle the reticle in a cleanroom environment and to transfer the reticle between the cleanroom environment and the evacuated environment of the photolithography tool.

Certain reticle pod products have a “dual-pod” design that includes an inner reticle pod (a.k.a., “inner carrier” or “inner pod”) that holds and protects a reticle, and an outer reticle pod (a.k.a., “outer shell” or “outer pod”) that contains and transports the inner reticle pod. The inner reticle pod can be removed from the outer pod to transfer the reticle between a cleanroom and an evacuated interior of a photolithography tool. The inner reticle pod includes a flat lower piece referred to as a base that provides support for the reticle, and a cover that can be placed over the base and the reticle to define an interior that contains and protects the reticle. The cover includes reticle retainers that engage the reticle at the interior of the inner reticle pod to prevent movement of the reticle within the inner reticle pod. In a dual-pod design, the outer pod includes a lower piece or “door” that supports the inner reticle pod, and an upper piece or “dome” that covers the door and an inner reticle pod that is supported by the door. Example dual-pod designs are shown in United States Patent Publication 2021/0057248. The outer pod includes structures to prevent the inner reticle pod from moving within the outer pod.

### SUMMARY

The following describes containers or “pods” that are designed and adapted for use during the storage, transport, shipping, or processing of fragile devices such as photomasks, reticles, and wafers, and more particularly to dual containment or “dual-pod” reticle pod systems having an outer pod that includes a door and a dome, and is adapted to contain an inner reticle pod that includes an inner reticle pod base, an inner reticle pod cover, and is adapted to contain a reticle. The inner reticle pod base includes reticle supports that support the reticle. The inner reticle pod cover includes one or more reticle retainers that extend through the inner reticle pod cover. Each reticle retainer includes an inner retainer contact and an outer retainer contact. The inner retainer contact can be actuated by applying pressure to the outer retainer contact, which is located at an exterior of the inner reticle cover. Pressure applied to the outer retainer contact causes the inner retainer contact to move and engage the reticle at the inner reticle pod interior to limit movement of the reticle within the inner reticle pod interior.

Current dual-pod designs include multiple “dome pads” that are located at an underside of the dome interior. The dome is a generally rectangular-shaped (e.g., square-shaped) cover that includes a generally horizontally-extending top and four sidewalls that extend vertically down from the top to form a dome interior that is surrounded by the top and the sidewalls. The dome interior includes an upper interior surface on an underside interior of the dome. Dome pads of current dual-pod designs are located at the upper interior surface of the dome interior and are arranged to contact and apply pressure at separate locations on the inner reticle pod cover when the outer pod dome is placed over an inner reticle pod that is supported by the door. These dome pads are typically compressible (e.g., spring-loaded) structures at the underside of the dome interior that extend toward the inner reticle pod cover, to apply pressure to a specific location on the inner reticle pod cover.

One type of dome pad, a “retainer pad,” engages and applies pressure to an outer retainer contact of a reticle retainer of an inner reticle pod cover. When the retainer pad engages the outer retainer contact, pressure applied to the outer retainer contact actuates the reticle retainer, which causes the inner retainer contact to move into contact with a reticle at the inner reticle pod interior. A second type of dome pad, a “cover pad,” engages an outer surface of the inner reticle pod cover to limit movement of the inner reticle pod within the outer pod.

A typical dome includes four retainer pads to engage four outer retainer contacts of an inner reticle pod cover, and four cover pads to engage four different locations of an outer surface of an inner reticle pod cover. The dome includes four sets each of a cover pad and a retainer pad, i.e., a total of eight individual dome pads, with each set of two dome pads being located generally at corners of the dome to contact eight surfaces at corners of the inner reticle pod cover. Typically, but not necessarily, the dome pads are incorporated into a “dome plate” that is secured to the underside interior of the dome.

According to the present description, instead of multiple reticle pads and cover pads that are used in previous domes, a dome of an outer pod includes one or more “dome clamps,” with each dome clamp having a set of two surfaces adapted to engage an inner reticle pod cover. Specifically, each dome clamp includes a first surface that is referred to herein as a “reticle clamp,” and a second surface that is referred to herein as a “cover clamp.” A single dome clamp that includes both a cover clamp and a reticle clamp can be used in place of two separate dome pads (the cover pad and the retainer pad) of previous dome designs. A total of four dome clamps, each having a reticle clamp and a cover clamp, can replace a total of eight dome pads of previous dome designs.

Example designs of a dome clamp may include a dome clamp body that includes a connector to attach the dome clamp body to an underside interior location of a dome, optionally, indirectly to an underside interior surface of the dome by being attached to a dome plate that is secured to the inner underside surface of the dome. The dome clamp body also includes two extensions or “legs” that extend laterally from the connector. At an end of one leg is a reticle clamp that is adapted to contact an outer retainer contact of an inner reticle pod cover. At an end of another leg is a cover clamp that is adapted to contact a surface of the inner reticle pod cover. According to certain specific examples, the dome clamp body is connected to a dome plate by a connector that includes a hinge to allow each leg to move vertically relative to the dome when pressure is applied to each leg.

In one aspect, this description relates to a pod that includes a door and a dome and that is adapted to contain an inner reticle pod. The pod includes: a door adapted to support an inner reticle pod, and a dome adapted to cover the door to enclose an inner reticle pod supported by the door. The dome includes a dome clamp connected to the dome interior. The dome clamp includes: a connector that connects the dome clamp to the dome interior; a first leg extending from the connector to a first leg end that comprises a reticle clamp; and a second leg extending from the connector to a second leg end that comprises a cover clamp.

In another aspect, the description relates to a method of containing an inner reticle pod in an outer pod. The method includes supporting an inner reticle pod on a door of an outer pod. The inner reticle pod includes a base, and an inner reticle pod cover located over the base to define an inner reticle pod interior. The inner reticle pod cover includes a reticle retainer extending through the inner reticle pod cover. The reticle retainer includes an outer retainer contact accessible at an exterior of the inner reticle pod cover and an inner retainer contact at the inner reticle pod interior. A reticle is supported by the base at the inner reticle pod interior. The method further includes: placing a dome over the base and the inner reticle pod, the dome including a dome clamp that has a dome clamp body that includes a cover clamp and a reticle clamp; causing the cover clamp to engage a surface of the inner reticle pod cover; and causing the reticle clamp to contact an outer retainer contact of the inner reticle pod cover.

In another aspect, the disclosure relates to a dome that is adapted for use in a dual-pod reticle container. The dome includes an exterior, a dome interior, an upper interior surface, and a dome clamp at the dome interior. The dome clamp includes: a connector that connects the dome clamp to the dome interior, a first leg extending from the connector to a first leg end that includes a reticle clamp, and a second leg extending from the connector to a second leg end that includes a cover clamp.

### BRIEF DESCRIPTION OF THE DRAWINGS

FIGS. 1A, 1B, and 1C show a side cut-away views of example dome clamps as described.

FIG. 2 shows a top view of an upper surface of an inner reticle pod cover, as described.

FIG. 3 shows a top view of an example dome plate having example dome hinges, as described.

FIG. 4A shows a top view of an example dome plate with dome hinges positioned over an example inner reticle pod cover, as described.

FIG. 4B shows a side cut-away view of an example dome plate with dome hinges positioned over an example inner reticle pod, as described.

FIG. 5 shows an exploded view of a dual-pod container that includes an outer pod and an inner reticle pod, as described.

All figures are schematic and not necessarily to scale.

### DETAILED DESCRIPTION

The present disclosure relates to containers, i.e., “pods,” for storing, transporting, shipping, or processing fragile devices such as photomasks, reticles, and wafers, including dual containment or dual-pod systems that include an outer pod that contains an inner reticle pod, which in turn contains a reticle.

The outer pod includes a door and a dome that can be assembled by placing the dome over the door to define an outer pod interior that is adapted to contain an inner reticle pod supported by the door. The inner reticle pod includes an inner reticle pod base and an inner reticle pod cover that can be assembled with the inner reticle pod cover being placed over the inner reticle pod base to define an inner reticle pod interior that is adapted to contain a reticle.

The inner reticle pod base includes reticle supports that support the reticle above an upper surface of the base. The inner reticle pod cover includes one or more reticle retainers, each of which includes an inner retainer contact at the inner reticle pod interior and an outer retainer contact that is accessible at an exterior of the inner reticle pod cover. In use, pressure applied to the outer retainer contact actuates the reticle retainer to cause the inner retainer contact to move and engage a reticle that is held in the inner reticle pod interior, to limit movement of the reticle within the inner reticle pod interior.

Conventional and currently-commercial dual-pod designs use a dome that includes multiple dome pads located at an underside of the dome interior, each of which contacts and applies pressure to a location at an exterior of the inner reticle pod cover when the dome is placed over the door.

As described herein, in the place of dome pads, a dome as described includes one or more dome clamps located at an underside of the dome interior. Each dome clamp includes a set of two clamp contact surfaces that are adapted to individually engage two locations at an exterior of an inner reticle pod cover when the dome is placed over the inner reticle pod and the door. The clamp contact surfaces operate similarly to previous dome pads but are included as part of a single dome clamp structure. Each dome clamp includes two clamp surfaces, one being a reticle clamp and one being a cover clamp. A single dome clamp that includes both a reticle clamp and a cover clamp can be used in place of two individual dome pads (the cover pad and the retainer pad) of previous dome designs. A total of four dome clamps can replace a total of eight dome pads of previous dome designs.

Example dome clamp designs include a dome clamp body that connects directly or indirectly to an underside interior location of a dome. The dome clamp body may be connected directly to an underside surface of the dome interior or may instead be connected indirectly to the underside surface of the dome interior by being attached to another structure, e.g., a dome plate that is secured to the underside surface of the dome interior.

A dome plate is a plate-like structure that attaches to an upper interior surface of a dome. A dome plate may be securely (permanently, non-removably) attached to the interior of the dome, e.g., by an adhesive, rivet, or the like, or may be selectively secured to and removed from the upper interior surface, e.g., by a removable fastening mechanism such as a bolt, clip, or screw.

A connector that connects a dome clamp to a dome can be any structure that provides a useful connection of the dome clamp body to an upper interior of a dome (e.g., a dome plate) in a manner that allows the dome clamp to function as described. The connector may be any mechanical structure that connects the dome clamp body to the dome, e.g., a connecting structure that is rigid, semi-rigid, flexible, or hinged; any such connecting structure is referred to herein as a “hinge” or a “hinged connector” because the dome clamp body and each of the first and second legs of the dome clamp body may move or flex vertically relative to the connector in response to pressure applied to one or both legs.

According to example dome clamps, a dome clamp body connects to the dome at a connector (e.g., a hinge or a hinged connector) at a central or approximately central location of the dome clamp body relative to the first and second legs. The dome clamp body includes two elongate legs. Each leg extends from the connector along a length to a leg end that includes a clamp surface. One leg includes a clamp surface that functions as a reticle clamp and one leg includes a clamp surface that functions as a cover clamp. The reticle clamp is adapted and positioned to contact an outer retainer contact of a reticle retainer of a reticle cover, when the dome is placed over the inner reticle pod and the door. The cover clamp is adapted and positioned to contact an outer surface of the inner reticle pod cover when the dome is placed over the inner reticle pod and the door.

The first leg and the second leg may each move vertically by flexing or pivoting relative to the dome clamp body or relative to the connection (e.g., hinge) when pressure is applied to the leg, for example when vertical pressure is applied to an end of the leg in a direction vertically (the z-direction) toward the dome. The first leg may be connected to the second leg through the dome clamp body, and each leg may move by pivoting or flexing in a vertical direction. According to example clamps, each leg may include or function as a spring such that when a clamp surface contacts an inner reticle pod cover (at an outer retainer contact of an inner reticle pod cover, or at an outer surface of an inner reticle pod cover) and pressure is applied to the clamp surface, the leg compresses or bends based on the force of the pressure and the required distance of the movement of the clamp surface.

Example clamp bodies and example legs may be made of polymeric material that allows the legs to perform as described, e.g., as a deformable, elastic spring that will bend or flex when a force is applied at the clamp surface in a direction generally vertically and perpendicular to the dome clamp and legs, as when the two clamp surfaces receive pressure from contact with two surfaces of an inner reticle pod cover. The first leg and the second leg may move or flex in opposite vertical directions, e.g., as a seesaw or teeter-totter, or the legs may move independently and in the same vertical direction with pressure applied separately to each leg. The direction and the amount of movement of each leg can depend on the distance of movement of a leg end relative to the dome or inner reticle pod cover.

Each leg has a length (in an x-direction) measured perpendicularly between the connector and the leg end and clamp surface, and a depth (in a z-direction) measured perpendicularly between the connector and the leg end and clamp surface. The length and the depth dimensions of each of two legs of a dome clamp may be the same or different. Using different length and depth dimensions of the two legs, the ratio of forces between the two legs can be adjusted and optionally balanced between the leg that includes the reticle clamp and the leg that includes the cover clamp, based on the amount of movement required of each leg when the retainer clamp contacts an outer retainer contact of a reticle cover and when the cover clamp contacts an outer surface of the inner reticle pod cover.

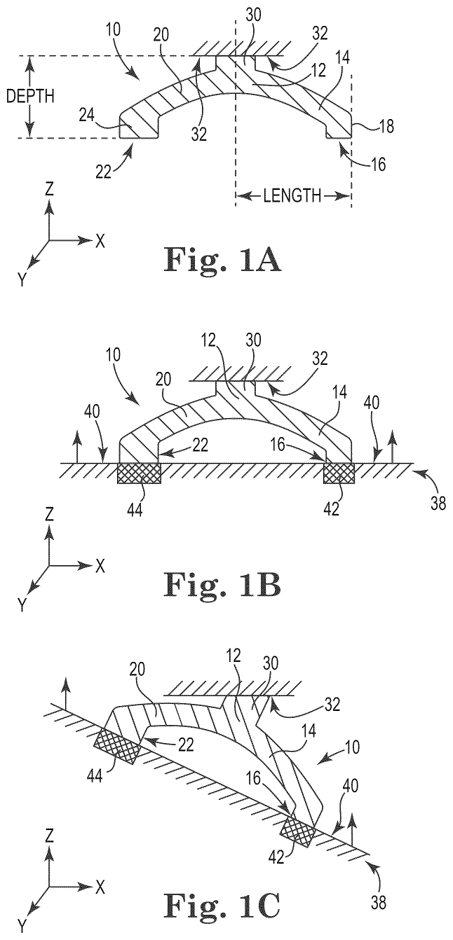

FIG. 1A shows a side-cross sectional view of example dome clamp 10 that includes body 12, first leg 14 having a first clamp, e.g., a reticle clamp 16 at an end 18 of the first leg, and second leg 20 having a second clamp, e.g., a cover clamp 22 at an end 24 of second leg 20. Body 12 is connected through connector 30 to dome plate 32, which is secured to an underside (not shown) of a dome interior; in alternate designs, connector 30 may be attached directly to an upper underside surface of the dome. When upward vertical pressure (upward, in a z-direction, see arrows) is applied to reticle clamp 16, to cover clamp 22, or both, each of first leg 14 and second leg 20 will move or flex based on the relative pressures applied to each clamp 16 and 22 and the required directions and distances of movement of each clamp. First leg 14 and second leg 20 may, depending on the relative pressures applied to each of clamp 16 and clamp 22, and based on the distance of movement of each clamp 16 and 22, individually flex by bending toward dome plate 32 (see FIG. 1B), or may pivot about connector 30 (see FIG. 1C), or both.

As shown at FIG. 1B, as dome clamp 10 moves vertically downward toward an upper surface 40 of inner reticle pod cover 38, reticle clamp 16 engages outer retainer contact 42 of upper surface 40 of inner reticle pod cover 38, and cover clamp 22 contacts outer surface 44 of upper surface 40. Upper surface 40 is relatively level, and each of leg 14 and 20 flexes or bends in an upward direction toward dome plate 32. As shown at FIG. 1C, body 12 and legs 14 and 20 may alternately move in opposite directions relative to dome plate 32 to engage an upper surface 40 of inner reticle pod cover 38 having a different shape or orientation, e.g., where outer retainer contact 42 and outer surface 44 of upper surface 40 are not level.

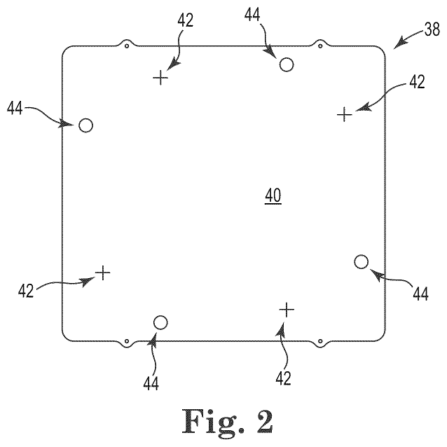

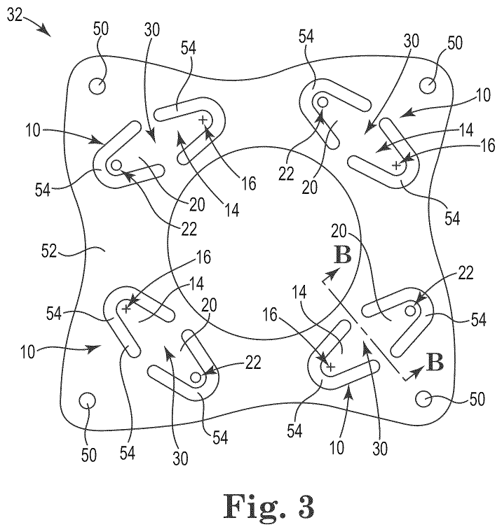

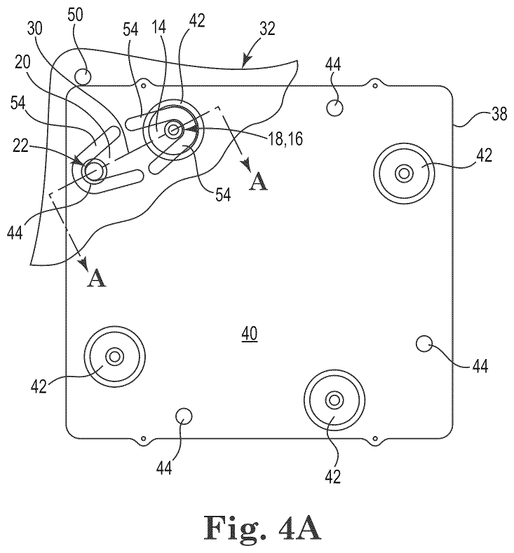

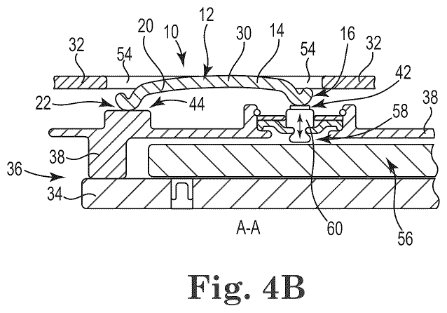

FIG. 2 shows an example of an upper surface 40 (top view) of an inner reticle pod cover 38 having four outer surfaces 44 and four reticle retainers (see example reticle retainer at FIG. 4B). Each reticle retainer has an outer retainer contact 42. Each set of an outer retainer contact 42 and an outer surface 44 is located generally at a corner of upper surface 40. During use, a dome that includes multiple (four, as exemplified, see FIG. 3) dome clamps 10 is lowered over a door of an outer pod that supports an inner reticle pod that includes inner reticle pod cover 38. Each of the four dome clamps 10 is generally located at a corner of the dome interior. Each dome clamp 10 includes a retainer clamp 16 and a cover clamp 22. When the dome is lowered toward inner reticle pod cover 38, each retainer clamp 16 contacts an outer retainer contact 42 and each cover clamp 22 contacts an outer surface 44.

FIG. 3 illustrates (top view) an example of dome plate 32, a horizontal, generally planar structure that includes plate member 52 and four dome clamps 10. Dome plate 32 can be secured to an underside of a dome interior using dome mounts 50. Dome plate 32 can be made of any useful material. As illustrated, dome plate 32 is a molded polymeric structure that includes the four dome clamps 10 integrally formed with plate member 52 by a molding process. The molded polymeric dome plate can be prepared by a molding process such as injection molding to form a dome plate that includes plate member 52 and one or more (e.g., four) dome hinges 10 integrally formed as dome plate 32 by a single molding step.

The four dome clamps 10 are located generally at corners of plate member 52. Each dome clamp 10 is attached to plate member 52 by connector 30, which is integrally formed by molding with plate member 52, and centrally located between legs 14 and 20. Each dome clamp 10 includes legs 14 and 20 having reticle clamp 16 and cover clamp 22, respectively, at the legends 18 and 24. Each leg and leg end is separated from plate member 52 by void space 54 to allow each leg and leg end to move vertically relative to plate member 52.

FIG. 4A shows a top view of dome plate 32 positioned over upper surface 40 of inner reticle pod cover 38. A leg 14 of dome clamp 10 extends from connector 30 to leg end 18 and retainer clamp 16, which are located at a position to engage outer retainer contact 42 of inner reticle pod cover 38 when the dome and dome plate 32 are placed over inner reticle pod cover 38. A leg 20 of dome clamp 10 extends from connector 30 to a location that allows cover clamp 22 to engage outer surface 44 of inner reticle pod cover 38, when the dome and dome plate 32 are placed over inner reticle pod cover 38.

FIG. 4B shows a cross section of plate 32 (A-A at FIG. 4B) and inner reticle pod 36 that includes inner reticle pod cover 38 positioned over base 34, which supports reticle 56. Base 34 is supported by a door (not shown) of an outer pod, with the door and the dome of the outer pod defining an outer pod interior. Dome plate 32 is located over inner reticle pod cover 38, with cover clamp 22 engaging outer surface 44 and with reticle clamp 16 engaging outer retainer contact 42. Cover clamp 22 contacts outer surface 44 to prevent movement of inner reticle pod 36 within the outer pod interior. Reticle retainer 60 includes outer retainer contact 42 and inner retainer contact 58. When dome plate 32 is lowered toward inner reticle pod 36, reticle clamp 16 engages outer retainer contact 42 of reticle retainer 60, which causes inner retainer contact 58 to move downward to engage reticle 56 to prevent movement of reticle 56 within the interior of inner reticle pod 36

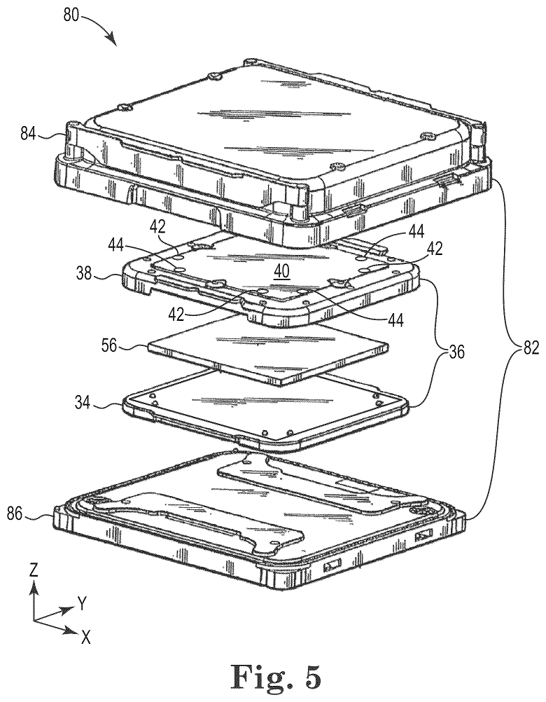

FIG. 5 is an exploded perspective view of an example dual containment pod 80. Dual containment pod 80 includes outer pod 82, having door 86 and dome 84. Dome 84 comprises an exterior, a dome interior, an upper interior surface (not visible), and a dome clamp (not visible) at the dome interior. Door 86 supports inner reticle pod 36 that contains reticle 56. Dual containment pod 80 can be, but is not limited to, a reticle pod for EUV processing of photolithography masks, or the like. Inner reticle pod 36 includes inner reticle pod cover 38, base 34, and contains reticle 56 at an interior of inner reticle pod 36. inner reticle pod cover 38 and base 34 are configured to be engaged at opposing perimeters to provide contact and sealing between base 34 and inner reticle pod cover 38. When so engaged, inner reticle pod cover 38 and base 34 define an inner reticle pod interior that is sized and shaped contain reticle 56.

Inner reticle pod cover 38 includes reticle retainers 60 (not specifically shown) having four outer retainer contacts 42 at upper surface 40 of inner reticle pod cover 38. With dome 84 placed over inner reticle pod cover 38, a reticle clamp of a dome clamp (not shown) located at an inner interior surface of dome 84 contacts an outer reticle contact 42 of a reticle retainer, which causes an inner reticle contact of the reticle retainer to move into contact with reticle 56 to prevent movement of reticle 56 within the interior of inner reticle pod 36 (see FIG. 4B). Upper surface 40 of inner reticle cover 38 also includes four outer surfaces 44. With dome 84 placed over inner reticle pod cover 38, a cover clamp of a dome clamp (not shown) contacts an outer surface 42 of inner reticle cover 38 to prevent movement of inner reticle pod 36 within the interior of outer pod 82.

Aspect 1. A pod comprising a door and a dome and adapted to contain an inner reticle pod, the pod comprising:
a door adapted to support an inner reticle pod,
a dome adapted to cover the door to enclose an inner reticle pod supported by the door, the dome comprising a dome clamp connected to the dome interior, the dome clamp comprising:
   a connector that connects the dome clamp to the dome interior,
   a first leg extending from the connector to a first leg end that comprises a reticle clamp, and
   a second leg extending from the connector to a second leg end that comprises a cover clamp.

Aspect 2. The pod of Aspect 1, wherein the first leg and the second leg are adapted to flex about the connector.

Aspect 3. The pod of Aspect 1, wherein the first leg and the second leg are capable of moving in opposite vertical directions about the connector.

Aspect 4. The pod of Aspect 1, wherein the first leg is flexible and the second leg is flexible such that when pressure is applied to the first leg and the second leg in a direction toward the dome, the first leg will bend toward the dome and the second leg will bend toward the dome.

Aspect 5. The pod of any of Aspects 1 through 4, wherein the dome comprises a dome plate at the dome interior and the connector is connected to the dome plate.

Aspect 6. The pod of Aspect 5, wherein the dome plate comprises a plate member and the dome clamp integrally formed with the plate member.

Aspect 7. The pod of any of Aspects 1 through 6, wherein the reticle clamp is located at a first length (x-direction) from the connector, the cover clamp is located a second length (x-direction) from the connector, and the first length is approximately equal to the second length.

Aspect 8. The pod of any of Aspects 1 through 6, wherein the reticle clamp is located at a first length (x-direction) from the connector, the cover clamp is located a second length (x-direction) from the connector, and the first length is greater than or less than the second leg length.

Aspect 9. The pod of any of Aspects 1 through 8, wherein the reticle clamp is located at a first depth (y-direction) from the connector, the cover clamp is located a second depth (y-direction) from the connector, and the first depth is approximately equal to the second depth

Aspect 10. The pod of any of Aspects 1 through 8, wherein the reticle clamp is located at a first depth (y-direction) from the connector, the cover clamp is located a second depth (y-direction) from the connector, and the first depth is greater than or less than the second depth.

Aspect 11. The pod of any of Aspects 1 through 10, comprising an inner reticle pod supported by the door, the inner reticle pod comprising:
an inner reticle pod base supported by the door,
a reticle supported by the inner reticle pod base,
an inner reticle pod cover positioned over the inner reticle pod base and the reticle to define an inner reticle pod interior that contains the reticle, the inner reticle pod cover comprising a reticle retainer extending through the inner reticle pod cover, the reticle retainer comprising an outer retainer contact accessible at an exterior of the inner reticle pod cover and an inner retainer contact at the inner reticle pod interior, wherein pressure applied to the outer retainer contact causes the inner retainer contact to move.

Aspect 12. The pod of Aspect 11, wherein with the dome placed over the door to enclose the inner reticle pod, the reticle clamp contacts the outer retainer contact and the cover clamp contacts an outer surface of the inner reticle pod cover.

Aspect 13. The pod of Aspect 11, comprising a first dome clamp connected by a connector to the dome interior, a second dome clamp connected by a connector to the dome interior, a third dome clamp connected by a connector to the dome interior, and a fourth clamp connected by a connector to the dome interior, each of the four dome clamps being located at a corner of the dome interior, each of the four dome clamps comprising:
a first leg extending from the connector to a first leg end that comprises a reticle clamp, and
a second leg extending from the connector to a second leg end that comprises a cover clamp.

Aspect 14. A method of containing an inner reticle pod in a pod of any of Aspects 11 through 13, the method comprising:
placing an inner reticle pod on the door, and
placing the dome over the door to enclose the inner reticle pod with the reticle clamp contacting the outer retainer contact and the cover clamp contacting the inner reticle pod cover.

Aspect 15. The pod of any of Aspects 1 through 14, wherein the pod is rectangular, the inner reticle pod is rectangular, and the reticle is rectangular.

Aspect 16. A method of containing an inner reticle pod in an outer pod, the method comprising:
supporting an inner reticle pod on a door of an outer pod, the inner reticle pod comprising:
   a base, and
   an inner reticle pod cover located over the base to define an inner reticle pod interior, the inner reticle pod cover comprising a reticle retainer extending through the inner reticle pod cover, the reticle retainer comprising an outer retainer contact accessible at an exterior of the inner reticle pod cover and an inner retainer contact at the inner reticle pod interior,
   a reticle supported by the base at the inner reticle pod interior,
placing a dome over the base and the inner reticle pod, the dome comprising a dome clamp that comprises a dome clamp body comprising a cover clamp and a reticle clamp,
causing the cover clamp to engage a surface of the inner reticle pod cover, and
causing the reticle clamp to contact an outer retainer contact of the inner reticle pod cover.

Aspect 17. The method of Aspect 16, wherein: the dome clamp comprises a connector that connects the dome clamp body to the dome, the dome clamp body comprises a first leg that comprises the reticle clamp and a second leg that comprises the cover clamp, and the first leg and the second leg flex about the connector.

Aspect 18. The method of Aspect 16, wherein pressure applied to the reticle clamp causes the reticle clamp to move vertically in a first vertical direction and pressure applied to the cover clamp causes the cover clamp to move in a second vertical direction.

Aspect 19. The method of Aspect 16, wherein pressure applied to the reticle clamp causes the reticle clamp to move vertically in a vertical direction and pressure applied to the cover clamp causes the cover clamp to move in the same vertical direction.

Aspect 20. A dome adapted for use in a dual-pod reticle container, the dome comprising an exterior, a dome interior, an upper interior surface, and a dome clamp at the dome interior, the dome clamp comprising:
a connector that connects the dome clamp to the dome interior,
a first leg extending from the connector to a first leg end that comprises a reticle clamp, and
a second leg extending from the connector to a second leg end that comprises a cover clamp.

Aspect 21. The dome of Aspect 20, wherein the first leg and the second leg are adapted to flex about the connector.

Aspect 22. The dome of Aspect 20 or 21, wherein the first leg and the second leg are capable of moving in opposite vertical directions about the connector.

Aspect 23. The dome of any of Aspects 20 through 22, wherein the first leg is flexible and the second leg is flexible such that when pressure is applied to the first leg and the second leg in a direction toward the dome, the first leg will bend toward the dome and the second leg will bend toward the dome.

Aspect 24. The dome of any of Aspects 20 through 23, wherein the dome comprises a dome plate at the dome interior and the connector is connected to the dome plate.

What is claimed is:

1. A pod comprising a door and a dome and adapted to contain an inner reticle pod, the pod comprising:
a door adapted to support an inner reticle pod,
a dome adapted to cover the door to enclose an inner reticle pod supported by the door, the dome comprising a dome clamp connected to the dome interior, the dome clamp comprising:
a connector that connects the dome clamp to the dome interior,
a first leg extending from the connector to a first leg end that comprises a reticle clamp, and
a second leg extending from the connector to a second leg end that comprises a cover clamp.

2. The pod of claim 1, wherein the first leg and the second leg are adapted to flex about the connector.

3. The pod of claim 1, wherein the first leg and the second leg are capable of moving in opposite vertical directions about the connector.

4. The pod of claim 1, wherein the first leg is flexible and the second leg is flexible such that when pressure is applied to the first leg and the second leg in a direction toward the dome, the first leg will bend toward the dome and the second leg will bend toward the dome.

5. The pod of claim 1, wherein the dome comprises a dome plate at the dome interior and the connector is connected to the dome plate.

6. The pod of claim 5, wherein the dome plate comprises a plate member and the dome clamp integrally formed with the plate member.

7. The pod of claim 1, wherein the reticle clamp is located at a first length (x-direction) from the connector, the cover clamp is located a second length (x-direction) from the connector, and the first length is approximately equal to the second length.

8. The pod of claim 1, wherein the reticle clamp is located at a first length (x-direction) from the connector, the cover clamp is located a second length (x-direction) from the connector, and the first length is greater than or less than the second leg length.

9. The pod of claim 1, wherein the reticle clamp is located at a first depth (y-direction) from the connector, the cover clamp is located a second depth (y-direction) from the connector, and the first depth is approximately equal to the second depth.

10. The pod of claim 1, wherein the reticle clamp is located at a first depth (y-direction) from the connector, the cover clamp is located a second depth (y-direction) from the connector, and the first depth is greater than or less than the second depth.

11. The pod of claim 1, comprising an inner reticle pod supported by the door, the inner reticle pod comprising:
an inner reticle pod base supported by the door,
a reticle supported by the inner reticle pod base,
an inner reticle pod cover positioned over the inner reticle pod base and the reticle to define an inner reticle pod interior that contains the reticle, the inner reticle pod cover comprising a reticle retainer extending through the inner reticle pod cover, the reticle retainer comprising an outer retainer contact accessible at an exterior of the inner reticle pod cover and an inner retainer contact at the inner reticle pod interior, wherein pressure applied to the outer retainer contact causes the inner retainer contact to move.

12. The pod of claim 11, wherein with the dome placed over the door to enclose the inner reticle pod, the reticle clamp contacts the outer retainer contact and the cover clamp contacts an outer surface of the inner reticle pod cover.

13. The pod of claim 11, comprising a first dome clamp connected by a connector to the dome interior, a second dome clamp connected by a connector to the dome interior, a third dome clamp connected by a connector to the dome interior, and a fourth clamp connected by a connector to the dome interior, each of the four dome clamps being located at a corner of the dome interior, each of the four dome clamps comprising:
a first leg extending from the connector to a first leg end that comprises a reticle clamp, and
a second leg extending from the connector to a second leg end that comprises a cover clamp.

14. A method of containing an inner reticle pod in a pod of claim 1, the method comprising:
placing an inner reticle pod on the door, and
placing the dome over the door to enclose the inner reticle pod with the reticle clamp contacting the outer retainer contact and the cover clamp contacting the inner reticle pod cover.

15. The pod of claim 1, wherein the pod is rectangular, the inner reticle pod is rectangular, and the reticle is rectangular.

16. A method of containing an inner reticle pod in an outer pod, the method comprising:
supporting an inner reticle pod on a door of an outer pod, the inner reticle pod comprising:
a base, and
an inner reticle pod cover located over the base to define an inner reticle pod interior, the inner reticle pod cover comprising a reticle retainer extending through the inner reticle pod cover, the reticle retainer comprising an outer retainer contact accessible at an exterior of the inner reticle pod cover and an inner retainer contact at the inner reticle pod interior,
a reticle supported by the base at the inner reticle pod interior,
placing a dome over the base and the inner reticle pod, the dome comprising a dome clamp that comprises a dome clamp body comprising a cover clamp and a reticle clamp,
causing the cover clamp to engage a surface of the inner reticle pod cover, and
causing the reticle clamp to contact an outer retainer contact of the inner reticle pod cover.

17. The method of claim 16, wherein: the dome clamp comprises a connector that connects the dome clamp body to the dome, the dome clamp body comprises a first leg that comprises the reticle clamp and a second leg that comprises the cover clamp, and the first leg and the second leg flex about the connector.

18. The method of claim 16, wherein pressure applied to the reticle clamp causes the reticle clamp to move vertically in a first vertical direction and pressure applied to the cover clamp causes the cover clamp to move in a second vertical direction.

19. The method of claim 16, wherein pressure applied to the reticle clamp causes the reticle clamp to move vertically in a vertical direction and pressure applied to the cover clamp causes the cover clamp to move in the same vertical direction.
